(19) United States
(12) Patent Application Publication
(10) Pub. No.: US 2008/0181277 A1
(43) Pub. Date: Jul. 31, 2008

(54) Semiconductor laser and method for producing the same

(75) Inventors: Harald Konig, Bernhardswald (DE); Martin Muller, Regenstauf (DE); Marc Philippens, Regensburg (DE)

Correspondence Address: COHEN PONTANI LIEBERMAN & PAVANE LLP, Suite 1210, 551 Fifth Avenue, New York, NY, 10176, US

(73) Assignee: Osram Opto Semiconductors GmbH, Regensburg (DE)

(21) Appl. No.: 11/906,449

(22) Filed: Oct. 1, 2007

(30) Foreign Application Priority Data
Sep. 29, 2006 (DE) 10 2006 046 295.5
Jan. 11, 2007 (DE) 10 2007 001 743.1

(51) Int. Cl. H01S 5/024; C23C 16/452

(52) U.S. Cl. 372/49.01; 427/249.1

(57) ABSTRACT

A semiconductor laser comprising a laser-active layer sequence (1) having a first main face (1003), on which is arranged a heat conducting layer (3) containing carbon nanotubes (30) and a method for producing such a semiconductor laser.

### RELATED APPLICATIONS

This patent application claims the priority of German patent applications 10 2006 046 295.5 filed Sep. 29, 2006 and 10 2007 001 743.1 filed Jan. 11, 2007, the disclosure content of both of which is hereby incorporated by reference.

### FIELD OF THE INVENTION

The invention relates to a semiconductor laser and a method for producing the same.

### BACKGROUND OF THE INVENTION

The emission properties of a semiconductor laser depend to a very great extent on the temperature in the active region of the laser. An increase in the temperature of the active region as a result of heat loss that arises in the active region during operation of the semiconductor laser leads to an inadequate emission characteristic of the semiconductor laser.

### SUMMARY OF THE INVENTION

It is an object of the invention to provide a semiconductor laser in which loss heat is transported away particularly efficiently from the active region.

This and other objects are attained in accordance with one aspect of the invention directed to a semiconductor laser comprising a laser-active semiconductor layer sequence having a first main face, on which is arranged a heat conducting layer containing carbon nanotubes.

A semiconductor laser according to an embodiment of the invention comprises, in particular, a laser-active semiconductor layer sequence and a heat conducting layer, which has carbon nanotubes and which is arranged on the semiconductor layer sequence. The heat conducting layer is arranged on a first main face of the semiconductor layer sequence. The heat conducting layer, therefore, covers the semiconductor layer sequence in places or completely in a plan view of the first main face. The main planes of extension of the semiconductor layer sequence and of the heat conducting layer are parallel to one another, such that the first main face of the semiconductor layer sequence and a main face of the heat conducting layer face one another and/or adjoin one another.

In this case, the expressions “arranged on the semiconductor layer sequence” and “arranged on a first main face of the semiconductor layer sequence” encompass both embodiments in which the heat conducting layer directly adjoins the semiconductor layer sequence and those embodiments in which at least one further layer is arranged between the semiconductor layer sequence and the heat conducting layer.

The laser-active semiconductor layer sequence has an active region, in particular an active layer, provided for generating laser radiation.

The active region comprises a laser-active pn junction. The laser-active pn junction has for example a double heterostructure, a single quantum well (SQW) or a multiple quantum well structure (MQW) for generating radiation. In this case, the term quantum well structure does not comprise any indication about the dimensionality of the quantization. It therefore encompasses, inter alia, quantum wells, quantum wires and quantum dots and any combination of these structures. Examples of MQW structures are described in the documents U.S. Pat. No. 6,849,881 U.S. Pat. No. 5,831,277, U.S. Pat. No. 6,172,382 B1 and U.S. Pat. No. 5,684,309, the disclosure content of which is in this respect hereby incorporated by reference.

Laser radiation generated during operation of the semiconductor laser is emitted either through a flank of the laser-active semiconductor layer sequence (edge emitter), or through a main face of the semiconductor layer sequence (surface emitter). The active region of the laser-active semiconductor layer sequence is electrically pumped during operation of the semiconductor laser, that is to say by an electric current being impressed into the laser-active semiconductor layer sequence, and/or said active region is optically pumped, that is to say by the laser-active semiconductor layer sequence being irradiated with electromagnetic radiation. In this case, the electric current and/or the electromagnetic radiation are expediently suitable for generating a population inversion in the active region.

In one advantageous embodiment, the laser-active semiconductor layer sequence comprises a pump radiation source suitable for optically pumping the active region.

Examples of laser-active semiconductor layer sequences and of methods for producing them are described in the documents U.S. Pat. No. 6,944,199 and U.S. Pat. No. 6,954,479, the disclosure content of which is in this respect hereby incorporated by reference.

The carbon nanotubes contained in the heat conducting layer are tubular, generally microscopically small structures which contain or consist of carbon. As in the case of graphite, the carbon atoms of a carbon nanotube generally have three closest carbon neighbors. The carbon atoms form a honeycomb-like structure which usually has predominantly or exclusively hexagonal basic units. The carbon atoms are situated in the corners of the basic units. Whereas in the case of graphite the honeycomb-like structure extends in a plane, it is bent to form a tube in the case of carbon nanotubes, said tube generally having a circular or elliptical cross section.

In one embodiment, at least some, but preferably a majority or all, of the carbon nanotubes are closed on at least one side. As an alternative or in addition, they can also be subdivided into a plurality of segments by separating layers which contain carbon atoms and which essentially run parallel to the base area of the carbon nanotube. By way of example, the separating layers are monolayers composed of carbon atoms.

The heat conducting layer contains single-walled carbon nanotubes, multi-walled carbon nanotubes and/or carbon nanotubes with walls which are spiral in a plan view of the base area of the carbon nanotube.

The heat conducting layer can be composed practically exclusively of carbon. Although the heat conducting layer can be composed substantially of carbon, it can happen—for example due to the production method—that the carbon in the heat conducting layer is not present exclusively in the form of nanotubes, but rather e.g. also as graphite, as fullerenes and/or amorphously. Preferably, however, a highest possible proportion of the heat conducting layer has carbon nanotubes. By way of example, the proportion of the area covered by carbon nanotubes in a plan view of a main face of the heat conducting layer is greater than or equal to 30%, preferably greater than or equal to 50%.

The thickness of the walls is for example between 1 and 15 nm, preferably between 5 and 10 nm. The external diameter of the base area of a carbon nanotube, to put it another way the cross section of the carbon nanotube, is for example between 5 and 50 nm, preferably between 15 and 25 nm. The length of the carbon nanotube is for example between 1 μm and 500 μm. Preferably, a plurality of the carbon nanotubes have a length of between 1 and 20 μm, preferably between 3 and 10 μm. Particularly preferably, the heat conducting layer has a thickness which corresponds at least substantially to the length or to an average length of the carbon nanotubes. In an alternative embodiment, the thickness of the heat conducting layer corresponds to an integral multiple of the length or the average length of the carbon nanotubes.

The heat conducting layer having carbon nanotubes advantageously has a particularly high thermal conductivity. The loss heat generated in the laser-active semiconductor layer sequence, in particular in the active region, is thus dissipated particularly effectively. In particular, the thermal conductivity is advantageously significantly increased compared with conventional heat conducting layers having gold or diamond, for example. By way of example, the thermal conductivity of the heat conducting layer having carbon nanotubes is greater than or equal to 3000 W/mK, preferably greater than or equal to 4000 W/mK. In a particularly advantageous embodiment, it is between 4000 and 6000 W/mK. The thermal conductivity is therefore advantageously greatly increased compared with that of gold and diamond, which are used in conventional heat conducting layers and which have a thermal conductivity of 312 and 2000 W/mK, respectively.

In addition, in an advantageous manner, the heat conducting layer having carbon nanotubes enlarges in a particularly effective manner the area over which loss heat is emitted from the semiconductor laser. In the semiconductor laser, the loss heat emerges generally from a spatially narrowly delimited region. In particular, said region essentially corresponds to the region in which the laser radiation is generated and/or in which the semiconductor layer sequence is electrically and/or optically pumped. In a plan view of a main face of the laser-active semiconductor layer sequence, the laser radiation and thus also the loss heat are therefore generated only at one location, for example a strip, or at some locations of the laser-active semiconductor layer sequence. The heat conducting layer advantageously distributes the loss heat over a greatest possible part of the area, preferably over the entire area, of the heat conducting layer. Thus, the thermal resistance, which is inversely proportional to the area, is advantageously reduced. By way of example, the loss heat is thereby emitted from the semiconductor laser to the surroundings in a particularly efficient manner. Thus, the semiconductor laser has in particular a particularly high efficiency and during operation emits a laser beam having particularly good beam quality.

In one advantageous embodiment, at least some, but preferably a majority or all, of the carbon nanotubes are partly or completely filled with a filling material. By way of example, silver, lead and noble gases such as helium, neon and/or argon are conceivable as filling materials. The thermal conductivity of the carbon nanotubes with filling material is advantageously increased further.

In one advantageous embodiment, the heat conducting layer contains a first plurality of carbon nanotubes oriented essentially parallel to one another. By way of example, carbon nanotubes of the first plurality of carbon nanotubes run essentially parallel to the main plane of extension of the heat conducting layer. As an alternative, they can also run at an angle with respect to the main plane of extension of the heat conducting layer. By way of example, they run essentially perpendicularly to the main plane of extension of the heat conducting layer.

In an advantageous manner, a particularly high thermal conductivity can be obtained with a heat conducting layer having carbon nanotubes oriented in a defined manner with respect to one another.

In a further advantageous embodiment, the heat conducting layer contains a second plurality of carbon nanotubes oriented essentially parallel to one another and at an angle, for example perpendicularly, with respect to the direction along which the first plurality of carbon nanotubes runs. Analogously to the first plurality of carbon nanotubes, the second plurality of carbon nanotubes can run essentially parallel or at an angle, in particular essentially perpendicularly, with respect to the main plane of extension of the laser-active semiconductor layer sequence.

As an alternative to this, the orientation of the carbon nanotubes can be randomly distributed. Preferably, however, a portion, in particular a majority or all, of the carbon nanotubes have a defined orientation; to put it another way, preferably a portion, in particular a majority or all, of the carbon nanotubes belong to the first plurality, or to the first and second pluralities of carbon nanotubes. Thus, the direction along which a particularly good heat conduction takes place in the heat conducting layer can advantageously be set in a defined manner.

By way of example, the heat conducting layer contains a first layer, which has the first plurality of carbon nanotubes, and a second layer, which has the second plurality of carbon nanotubes. The first and the second layers adjoin one another, for example, or they are spaced apart from one another. Preferably, the first layer does not have the second plurality of carbon nanotubes and/or the second layer does not have the first plurality of carbon nanotubes. In other words, the first layer preferably essentially contains carbon nanotubes running in a first direction, and the second layer essentially contains carbon nanotubes running in a second direction, the second direction being different from the first direction.

In one embodiment, a main face of the laser-active semiconductor layer sequence is completely or at least practically completely covered by the heat conducting layer. In another embodiment, the heat conducting layer covers a main face of the laser-active semiconductor layer sequence only in places. To put it another way, the heat conducting layer is patterned in this embodiment. The patterning of the heat conducting layer takes place for example during the production of the heat conducting layer, for instance by means of depositing the heat conducting layer through a shadow mask. As an alternative, a heat conducting layer produced over the whole area can subsequently be patterned. By way of example, the subsequent patterning comprises a photolithography process.

In a particularly advantageous embodiment, the heat conducting layer is electrically conductive. In particular, the carbon nanotubes contained in the heat conducting layer, or at least a majority of said carbon nanotubes are or is electrically conductive. The heat conducting layer therefore advantageously has both a good thermal conductivity and a good electrical conductivity.

In one advantageous embodiment, a metallic layer is arranged between the laser-active semiconductor layer sequence and the heat conducting layer.

The metallic layer contains at least one metal or comprises a metal. By way of example, the metallic layer has Ag, Au, Pt, Ti, W and/or Fe. In one advantageous embodiment, the metallic layer has a multilayer structure. By way of example, it comprises a metal layer having Ag, for example, a diffusion barrier having TiWN and/or Ti/Pt, for example, and/or a further metal layer having Fe, for example.

In an advantageous manner, particularly homogeneous current impressing into the laser-active semiconductor layer sequence is obtained with the metallic layer. In addition, the heat conducting layer having carbon nanotubes can be produced in a particularly simple manner on the metallic layer, for example by means of chemical vapor deposition. Furthermore, in an advantageous manner, particularly good thermal coupling of the heat conducting layer to the semiconductor layer sequence is obtained with the metallic layer.

The diffusion barrier for example advantageously prevents or reduces the penetration of a soldering metal through the metallic layer into the laser-active semiconductor layer sequence.

Preferably, the heat conducting layer adjoins the metallic layer. Particularly preferably, the metallic layer additionally or alternatively adjoins the laser-active semiconductor layer sequence. The thickness of the metallic layer is less than or equal to 10 μm, for example. In one embodiment, it is less than or equal to 50 nm, for example approximately 10 nm.

In one alternative embodiment, the heat conducting layer directly adjoins the laser-active semiconductor layer sequence.

Advantageously, the heat conducting layer is therefore applied directly on the laser-active semiconductor layer sequence or is at only a small distance from the latter. Thus, advantageously, the loss heat generated in the laser-active semiconductor layer sequence during operation of the semiconductor laser is distributed over a large area particularly close to the laser-active semiconductor layer sequence and is conducted away from the laser-active semiconductor layer sequence particularly efficiently. As a result, the temperature of the active region is kept particularly low.

In one advantageous embodiment, a further metallic layer is adjacent to that main face of the heat conducting layer which is remote from the laser-active semiconductor layer sequence. By way of example, the further metallic layer constitutes an electrical connection layer by means of which an electric current is fed to the laser-active semiconductor layer sequence in particular during operation, said electric current being provided in particular for electrically pumping the semiconductor laser.

In another embodiment, the semiconductor laser has a plurality of heat conducting layers having carbon nanotubes. By way of example, it has an alternate sequence of metallic layers and heat conducting layers. Thus, in an advantageous manner, a particularly efficient heat dissipation from the laser-active semiconductor layer sequence and, in particular, a particularly large-area distribution of the loss heat, and also a particularly homogeneous current impressing into the laser-active semiconductor layer sequence are obtained.

In one preferred embodiment, the semiconductor laser has a heat sink, in particular following that main face of the heat conducting layer or of the heat conducting layers which is remote from the laser-active semiconductor layer sequence. The heat conducting layer or the heat conducting layers is or are therefore preferably arranged between the semiconductor layer sequence and the heat sink.

In this embodiment, the loss heat generated in the laser-active semiconductor layer sequence, or at least a portion, in particular a majority, thereof, is transported from the heat conducting layer and, if appropriate, from the metallic layer or the metallic layers to the heat sink and emitted via the latter to the surroundings, for example.

Preferably, the heat sink is mechanically stably connected to the laser-active semiconductor layer sequence, for example by means of a fixing layer, which preferably contains or consists of a solder, for instance at least one soldering metal such as Au, AuSn, Pd, In and/or Pt, or an adhesive.

In a further embodiment, the semiconductor laser comprises at least one Bragg reflector (DBR, distributed Bragg reflector) which comprises, in particular, a sequence of dielectric, semiconducting and/or metallic layers having alternately a high and a low refractive index. The Bragg reflector is preferably monolithically integrated into the laser-active semiconductor layer sequence. By way of example, the Bragg reflector is part of a resonator of the semiconductor laser.

Another aspect of the invention is directed to a method for producing a semiconductor laser comprising the steps of:

providing a laser-active semiconductor layer sequence, and

producing a heat conducting layer, having carbon nanotubes, on the laser-active semiconductor layer sequence.

The heat conducting layer is preferably produced in such a way that the heat conducting layer essentially only contains carbon.

By way of example, the method for producing the heat conducting layer comprises vapor deposition, preferably chemical vapor deposition (CVD), by means of which the heat conducting layer is applied to the laser-active semiconductor layer sequence. In one advantageous embodiment, the heat conducting layer is produced by means of plasma-based chemical vapor deposition. The vapor deposition preferably takes place at a temperature of less than or equal to 350° C. This, advantageously prevents damage and/or degradation of the laser-active semiconductor layer sequence during the production of the heat conducting layer.

As an alternative, the carbon nanotubes can also firstly be produced separately and can be applied as heat conducting layer to the laser-active semiconductor layer sequence, for instance by drying of a solution.

Suitable production methods for carbon nanotubes are described for example in the documents Mi Chen et al., “Preparation of high-yield multi-walled carbon nanotubes by microwave plasma chemical vapor deposition at low temperature”, Journal of Materials Science, vol. 37, pages 3561-3567 (2002); Ming-Wei Li et al., “Low-temperature synthesis of carbon nanotubes using corona discharge plasma reaction at atmospheric pressure”, Journal of Materials Science Letters, vol. 22, pages 1223-1224 (2003); and Wenzhong Wang et al., “Low temperature solvothermal synthesis of multiwall carbon nanotubes”, Nanotechnology, vol. 16, pages 21-23 (2005), the disclosure content of which is in this respect hereby incorporated by reference.

In one embodiment, the heat conducting layer is produced, in particular deposited, directly on the laser-active semiconductor layer sequence. In an alternative embodiment, it is deposited or produced in some other way on a further layer, for example a metallic layer, which is arranged on the laser-active semiconductor layer sequence. The further layer is produced for example in an additional process step, preceding the production of the heat conducting layer, on the laser-active semiconductor layer sequence.

For example in contrast to a heat conducting layer composed of diamond, it is advantageously not necessary to fix the heat conducting layer on the laser-active semiconductor layer sequence by means of an adhesive or soldering agent. In particular, the carbon nanotubes are not intermixed with a matrix material, for instance with an adhesive. For example since adhesive-bonding or soldering locations generally have increased thermal resistance, particularly good thermal and/or electrical coupling of the heat conducting layer—in particular of the carbon nanotubes—to the laser-active semiconductor layer sequence is thus advantageously obtained. Moreover, the production of the semiconductor laser is simplified by the omission of the adhesive-bonding or soldering process.

### BRIEF DESCRIPTION OF THE DRAWINGS

FIG. 1 shows a schematic cross section through a semiconductor laser in accordance with a first exemplary embodiment;

FIG. 2 shows a schematic cross section through a semiconductor laser in accordance with a second exemplary embodiment;

FIG. 3 shows a schematic cross section through a semiconductor laser in accordance with a third exemplary embodiment;

FIG. 4 shows a schematic sectional illustration of the heat conducting layer of the semiconductor laser in accordance with the first exemplary embodiment;

FIG. 5 shows a schematic sectional illustration of a heat conducting layer in accordance with one variant of the first exemplary embodiment; and

FIG. 6 shows a schematic sectional illustration of a semiconductor laser in accordance with a fourth exemplary embodiment.

### DETAILED DESCRIPTION OF THE DRAWINGS

In the exemplary embodiments and figures, similar or similarly acting component parts are in each case provided with the same reference symbols. The illustrated elements and their size relationships among one another should not be regarded as true to scale, rather individual elements, such as e.g. layers, may be illustrated with an exaggerated size or thickness for the sake of better representability and/or for the sake of better understanding.

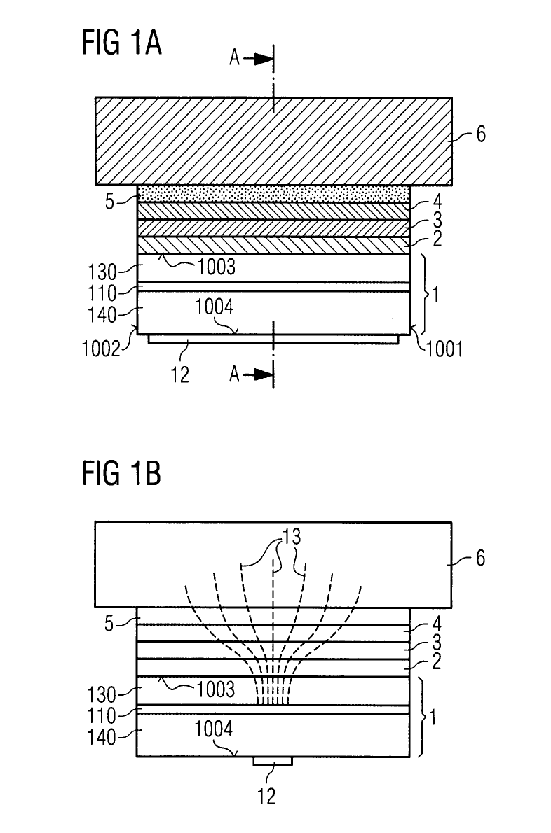

The semiconductor laser in accordance with the first exemplary embodiment illustrated in FIG. 1 comprises a laser-active semiconductor layer sequence 1 containing an active layer 110.

Suitable semiconductor material systems for the semiconductor layer sequence 1 are, inter alia, semiconductor materials based on GaAs, InP, InGaAs, AlGaAs, InGaAlAs, InGaP, InGaAsP, InGaAIP or a combination of at least two of said materials.

By way of example, in the present context “semiconductor material based on InGaAs” means that the semiconductor layer sequence 1 or at least one part thereof, for example the active layer 110, comprises or consists of an InGaAs semiconductor material, preferably InₙGaₘAs, where 0≦n≦1, 0≦m≦1 and n+m≦1. In this case, said material need not necessarily have a mathematically exact composition according to the above formula. Rather, it can have for example one or a plurality of dopants and also additional constituents. For the sake of simplicity, however, the above formula only comprises the essential constituents of the crystal lattice (In, Ga, As), even though these can be replaced in part by small quantities of further substances. This correspondingly applies to the rest of the semiconductor materials mentioned above.

In the present exemplary embodiment, the laser-active semiconductor layer sequence 1 is based on an InGaAs/AIGaAs semiconductor material system. The active layer 110 is formed as a multiple quantum well structure and has a plurality of quantum wells comprising undoped InGaAs. The active layer 110 is arranged between an n-type cladding layer 130 and a p-type cladding layer 140. By way of example, charge carrier confinement is obtained with the n-type cladding layer 130 and the p-type cladding layer 140. As an alternative or in addition, the n-type claddin layer 130 or a partial region thereof and the p-type cladding layer 140 or a partial region thereof preferably constitute a waveguide suitable for guiding laser radiation generated in the active layer 110 during operation of the semiconductor laser.

The semiconductor laser in accordance with the first exemplary embodiment is an edge emitter, the flanks 1001, 1002 of which are formed as a resonator. The laser radiation generated during operation is coupled out through at least one of the flanks 1001, 1002.

A first metallic layer 2 is arranged on the first main face 1003 of the laser-active semiconductor layer sequence 1. The first metallic layer 2 serves for charge carrier injection, for example. It has a high transverse electrical conductivity, such that homogeneous current impressing into the laser-active semiconductor layer sequence 1 is obtained.

A heat conducting layer 3 containing carbon nanotubes 30 is deposited on the first metallic layer 2. The deposition takes place for example by means of a microwave plasma-enhanced CVD method at a temperature of 330° C. or less, preferably of 300° C. or less. Such a method is described, in principle, for example in the document Mi Chen et al., “Preparation of high-yield multi-walled carbon nanotubes by microwave plasma chemical vapor deposition at low temperature”, Journal of Materials Science, vol. 37, pages 3561-3567 (2002), the disclosure content of which in this respect is incorporated by reference.

A second metallic layer 4, that is to say a layer 4 containing or consisting of a metal, is applied to the heat conducting layer 3. The second metallic layer 4 advantageously protects the heat conducting layer 3 from mechanical damage. In addition, simple and stable fixing of the laser-active semiconductor layer sequence 1 to a heat sink 6 is obtained with the second metallic layer 4. In this case, the adhesion is imparted for example by means of the fixing layer 5, which comprises or consists of a soldering metal such as AuSn. In order to reduce or entirely prevent diffusion of the soldering metal from the fixing layer 5 into the laser-active semiconductor layer sequence, the second metallic layer 4 in the present case comprises a diffusion barrier layer comprising TiWN. In the present case the second metallic layer 4 also constitutes an electrical connection layer.

The heat sink 6 comprises a metal plate, for example. Particularly efficient cooling is obtained with a heat sink 6 having a liquid cooling, for instance a water cooling. By way of example, the heat sink 6, in particular the metal plate, contains thin tubes through which a liquid such as water flows or is pumped during operation. The heat sink 6 then constitutes a microchannel cooler.

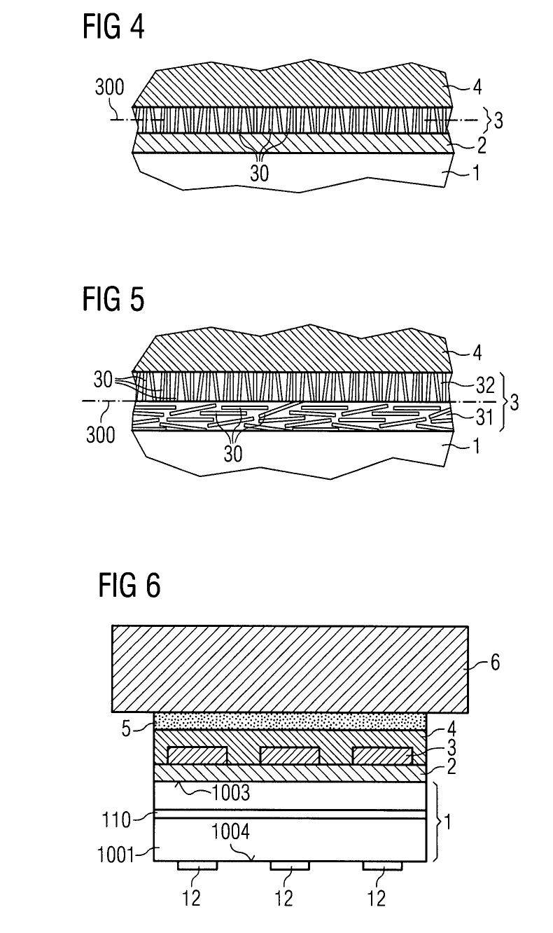

An excerpt from the heat conducting layer 3 is illustrated schematically in FIG. 4. The carbon nanotubes 30 contained in the heat conducting layer 3 are arranged perpendicularly or virtually perpendicularly to the main plane of extension 300 of the heat conducting layer 3. In other words, they run from the first metallic layer 2 in the direction toward the second metallic layer 4 and are essentially perpendicular to the main faces of the first and second metallic layer 2, 4 which face each other.

The semiconductor laser in accordance with the first exemplary embodiment is electrically pumped. For this purpose, the laser-active semiconductor layer sequence is electrically contact-connected by means of the heat sink 6 and the contact layer 12, which is applied in strip form on that main face 1004 of the laser-active semiconductor layer sequence 1 which is remote from the heat sink 6, and an electric current is impressed into the semiconductor layer sequence 1 during operation.

In a plan view of the heat sink 6 or of the main face 1004 of the laser-active semiconductor layer sequence 1 which is remote from the heat sink 6, loss heat is essentially generated in that region of the second main face 1004 which is covered by the contact area 12.

This is illustrated in FIG. 1B, which shows a schematic sectional illustration of the semiconductor laser in accordance with the first exemplary embodiment that is rotated by 90° about the axis A-A relative to FIG. 1A. The heat flow, indicated by dashed lines 13, is illustrated in a schematic and simplified manner in FIG. 1B.

The loss heat essentially emerges essentially from that region of the semiconductor layer sequence 1 which is covered by the contact layer 12 in a plan view of the second main face 1004. In the heat conducting layer 3, the heat flow is greatly spread out by the high thermal conductivity of the carbon nanotubes 30. To put it another way, the loss heat generated on a small, in the present case strip-shaped, area in a plan view of the main face 1004 is distributed over a larger area in the heat conducting layer 3. It is thus advantageously emitted to the surroundings better by means of the second metallic layer 4 and the heat sink 6; the active layer 110 advantageously has only a low temperature during operation of the semiconductor laser.

In one variant of this exemplary embodiment, the heat conducting layer comprises a first layer 31, neighboring the laser-active semiconductor layer sequence 1, and a second layer 32, which is arranged following that side of the first layer 31 which is remote from the semiconductor layer sequence 1 (cf. FIG. 5).

The carbon nanotubes 30 contained in the first layer 31, or at least a majority of said carbon nanotubes, run essentially parallel to the main plane of extension 300 of the heat conducting layer 3. By way of example, the first layer 31 thereby has a particularly good thermal conductivity parallel to the main plane of extension 300, such that the heat flow is spread out to a particularly great extent.

By contrast, the carbon nanotubes 30 contained in the second layer 32, or at least a majority of said carbon nanotubes, run essentially perpendicularly to the main plane of extension 300 of the heat conducting layer 3. In particular a particularly good dissipation of the loss heat from the semiconductor layer stack 1, which is adjoined directly by the heat conducting layer 3 in this variant, for example, is thereby obtained with the second layer 32.

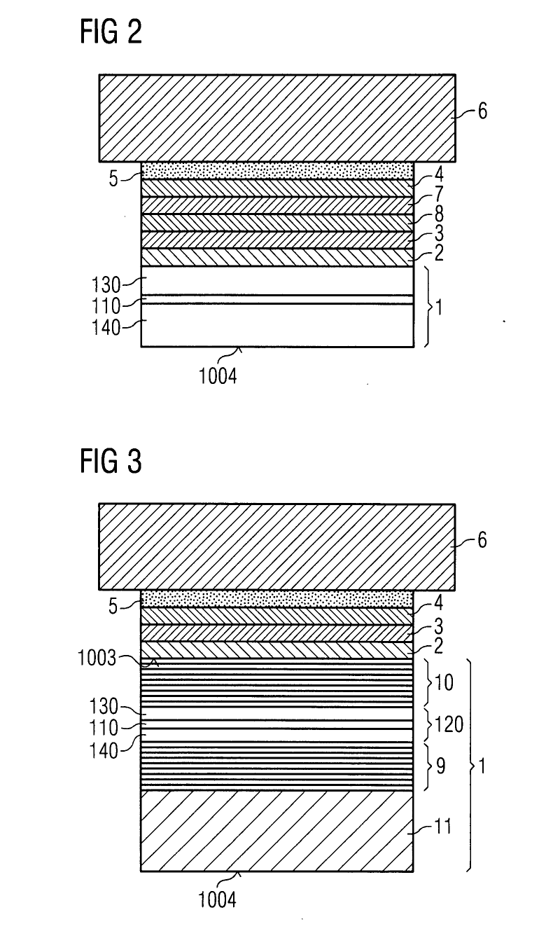

Instead of a single heat conducting layer 3 containing carbon nanotubes 30, the semiconductor laser in accordance with the exemplary embodiment illustrated in FIG. 2 has an alternate sequence of metallic layers 2, 4, 8 and heat conducting layers 3, 7 with carbon nanotubes 30. Thus, the heat generated in the laser-active semiconductor layer sequence 1 is advantageously distributed over an even larger area in a plan view of the second main face 1004 and is dissipated even more efficiently.

In contrast to the semiconductor lasers in accordance with the first and the second exemplary embodiment, the semiconductor laser in accordance with the third exemplary embodiment in FIG. 3 is a surface emitter. The laser radiation generated during operation of the semiconductor laser is coupled out through the second main face 1004 of the laser-active semiconductor layer sequence. In the present case, the resonator of the semiconductor laser comprises two Bragg reflectors 9, 10. The Bragg reflectors 9, 10 in each case comprise a layer stack composed of layers having alternately a high and a low refractive index.

Each Bragg reflector 9, 10 comprises for example 28 to 30 periods with in each case a GaAIAs (10% Al) layer and a GaAIAs (90% Al) layer. As an alternative, at least one Bragg reflector 9, 10 can be constructed from at least one transparent conducting oxide (TCO), for instance indium tin oxide (ITO). The refractive index of the transparent conducting oxide is varied from layer to layer for example by means of the growth parameters and/or by means of a dopant. The main planes of extension of the layers of the Bragg reflectors 9, 10 run essentially parallel to the first and second main face 1003, 1004 of the laser-active semiconductor layer sequence 1.

A part 120 of the laser-active semiconductor layer sequence 1 is arranged between the Bragg reflectors 9, 10, said part containing the active layer 110 and preferably constituting a waveguide for the radiation emitted by the active layer 110. By way of example, the waveguide 120 comprises the n-type cladding layer 130 and the p-type cladding layer 140. In the present case, the semiconductor layer sequence 1 also comprises a semiconductor layer 11, for instance a buffer layer, comprising undoped GaAs, for example.

The semiconductor laser in accordance with the fourth exemplary embodiment constitutes a laser bar whose active layer 110 emits a laser beam from its flank 1001 at a plurality of locations, in the present case three locations. The locations from which the laser beams are emitted are defined by the positions of the three contact layers 12 on the laser-active semiconductor layer sequence 1 (gain-guided laser). The heat conducting layer 3 is patterned in this exemplary embodiment. It is arranged in strips on the first metallic layer 2. In a plan view of the first main face 1003 of the semiconductor layer sequence 1, the strips lie above the locations of the active layer 110 from which a laser beam is emitted. The second metallic layer 4 is arranged on the heat conducting layer 3 and on those regions of the first metallic layer 2 which are not covered by said heat conducting layer.

The invention is not restricted to the exemplary embodiments by the description on the basis of said exemplary embodiments. Rather, the invention encompasses any new feature and also any combination of features, which in particular comprises any combination of features in the patent claims, even if this feature or this combination itself is not explicitly specified in the patent claims or exemplary embodiments.

We I claim:

1. A semiconductor laser comprising a laser-active semiconductor layer sequence having a first main face, on which is arranged a heat conducting layer containing carbon nanotubes.

2. The semiconductor laser as claimed in claim 1, in which at least some of the carbon nanotubes are closed on at least one side.

3. The semiconductor laser as claimed in claim 1, in which at least some of the carbon nanotubes are partly or completely filled with a filling material.

4. The semiconductor laser as claimed in claim 3, in which the filling material is selected from the group comprising silver, lead and the noble gases.

5. The semiconductor laser as claimed in claim 1, in which at least some of the carbon nanotubes are single-walled.

6. The semiconductor laser as claimed in claim 1, in which at least some of the carbon nanotubes are multi-walled.

7. The semiconductor laser as claimed in claim 1, comprising a first plurality of carbon nanotubes (30) oriented parallel to one another.

8. The semiconductor laser as claimed in claim 7, in which the first plurality of carbon nanotubes runs parallel to the main plane of extension of the heat conducting layer.

9. The semiconductor laser as claimed in claim 7, in which the first plurality of carbon nanotubes runs at an angle, in particular perpendicularly, with respect to the main plane of extension of the heat conducting layer.

10. The semiconductor laser as claimed in claim 7, comprising a second plurality of carbon nanotubes oriented parallel to one another and at an angle with respect to the direction along which the first plurality of carbon nanotubes runs.

11. The semiconductor laser as claimed in claim 10, in which the second plurality of carbon nanotubes runs parallel to the main plane of extension of the laser-active semiconductor layer sequence.

12. The semiconductor laser as claimed in claim 10, in which the second plurality of carbon nanotubes runs at an angle, in particular perpendicularly, with respect to the main plane of extension of the laser-active semiconductor layer sequence.

13. The semiconductor laser as claimed in claim 10, in which the heat conducting layer contains a first layer, which has the first plurality of carbon nanotubes and a second layer, which has the second plurality of carbon nanotubes, the first and the second layer adjoining one another, in particular.

14. The semiconductor laser as claimed in claim 13, in which the first layer does not have the second plurality of carbon nanotubes and/or the second layer does not have the first plurality of carbon nanotubes.

15. The semiconductor laser as claimed in claim 1, in which the heat conducting layer has a layer thickness corresponding to a length of the carbon nanotubes or to an integral multiple of the length.

16. The semiconductor laser as claimed in claim 1, in which the heat conducting layer is patterned.

17. The semiconductor laser as claimed in claim 1, in which the heat conducting layer is electrically conductive.

18. The semiconductor laser as claimed in claim 1, in which a metallic layer is arranged between the laser-active semiconductor layer sequence and the heat conducting layer.

19. The semiconductor laser as claimed in claim 18, in which the heat conducting layer adjoins the metallic layer.

20. The semiconductor laser comprising a plurality of heat conducting layers, having carbon nanotubes as claimed in claim 1.

21. The semiconductor laser as claimed in claim 20 comprising an alternate sequence of metallic layers and heat conducting layers having carbon nanotubes.

22. The semiconductor laser as claimed in claim 1, which has a heat sink.

23. The semiconductor laser as claimed in claim 22, in which the heat conducting layer or the heat conducting layers is/are arranged between the semiconductor layer sequence and the heat sink.

24. The semiconductor laser as claimed in claim 22, in which the laser-active semiconductor layer sequence is mechanically stably connected to the heat sink by means of a fixing layer.

25. The semiconductor laser as claimed in claim 24, in which the fixing layer comprises a solder or an adhesive.

26. The semiconductor laser as claimed in claim 1, which has at least one Bragg reflector.

27. A method for producing a semiconductor laser comprising the steps of:
providing a laser-active semiconductor layer sequence; and
producing a heat conducting layer, having carbon nanotubes, on the laser-active semiconductor layer sequence.

28. The method as claimed in claim 27, in which producing the heat conducting layer comprises chemical vapor deposition.

29. The method as claimed in claim 27, in which producing the heat conducting layer takes place at a temperature of less than or equal to 350° C.
